(19) United States
(12) Patent Application Publication
(10) Pub. No.: US 2011/0193139 A1
(43) Pub. Date: Aug. 11, 2011

(54) CELL MEASURING DEVICE

(75) Inventors: Toshiya SAKATA, Tokyo (JP); Sayaka KITA, Tokyo (JP)

(73) Assignee: The University of Tokyo, Tokyo (JP)

(21) Appl. No.: 12/852,205

(22) Filed: Aug. 6, 2010

(30) Foreign Application Priority Data
Feb. 5, 2010 (JP) 2010-024572

(51) Int. Cl. H01L 29/772

(52) U.S. Cl. 257/253; 257/E29.242

(57) ABSTRACT

There is provided a cell measuring apparatus that can measure cells efficiently. In a cell measuring apparatus 1 provided with an FET sensor 2, an accommodating cavity 21 that can accommodate a cell 15, is provided on a measuring section 20 on which cells immersed in a solution are mounted. The accommodating cavity 21 is formed in a mortar shape. By accommodating a cell 15 in the accommodating cavity 21, the cells 15 can be easily separated, so that measurement can be performed for each cell 15. Therefore the state of the respective cells can be more efficiently measured.

### FIELD OF THE INVENTION

The present invention relates to a cell measuring apparatus, and in particular to a measuring apparatus that uses a field effect transistor.

### BACKGROUND ART

As a cell measuring method that uses a field effect translator, there is disclosed a measuring method in which there is formed a complex comprising; a polypeptide including a VH region of an antibody that specifically recognizes a target substance, a polypeptide including a VL region of an antibody that specifically recognizes a target substance, and a target substance, and the complex is measured by a field effect transistor (for example Patent Document 1). According to the above Patent Document 1, the complex of the antigen/antibody can be detected directly using the field effect transistor without using a secondary antibody. Therefore a superior effect in that it can be measured simply and quickly, can obtained.

### Prior Art Documents

### [Patent Document]

[Patent Document 1] Japanese Unexamined Patent Publication No. 2009-133800

### SUMMARY OF THE INVENTION

### Problems that the Invention is to Solve

Also according to the above patent document, there are problems in that it is difficult to perform measurement efficiently.

Therefore, it is an object of the present invention to provide a cell measuring apparatus that can measure cells efficiently.

### Means to Solve the Problems

The invention according to a first aspect is characterized in that in a cell measuring apparatus provided with a first FET sensor, there is provided in a measurement section on which is mounted a cell immersed in a solution, an accommodating cavity for accommodating the cell.

The invention according to a second aspect is characterized in that the accommodating cavity is formed in a mortar shape.

The invention according to a third aspect is characterized in that the measuring section is formed with a cell flow path in which the solution including the cell flows, and the cell flow path is communicated with the accommodating cavity.

The invention according to a fourth aspect is characterized in that the measuring section is constituted by a transparent material.

The invention according to a fifth aspect is characterized in that the measuring section is electrically connected to a gate electrode of the first FET sensor, and is provided separate to the first FET sensor.

The invention according to a sixth aspect is characterized in that the measuring section is formed with a charge detecting section.

The invention according to a seventh aspect is characterized in that a mass detecting section formed from a transparent material, is provided on the measuring section, and the mass detecting section is electrically connected to a gate electrode of a second FET sensor.

The invention according to an eighth aspect is characterized in that the mass detecting section is constituted by a piezoelectric material, and is formed in a cantilever beam shape.

The invention according to a ninth aspect is characterized in that the charge detecting section is formed so as to surround a periphery of the load detecting section.

The invention according to a tenth aspect is characterized in that corrugations are formed on the surface of the measuring section on which the cells are mounted.

According to the present invention, cells are accommodated in the accommodating cavities so that the cells can be easily separated, making it possible to measure each cell. Therefore the state of each cell can be measured more efficiently.

### BRIEF DESCRIPTION OF THE DRAWINGS

FIG. 1 is a schematic diagram showing an overall configuration of a cell measuring apparatus according to a first embodiment.

FIG. 2 is a partial enlarged cross-sectional view of a measuring section according to a modified example of the first embodiment.

FIG. 3 is a partial enlarged cross-sectional view showing a configuration of a measuring section according to a second embodiment.

FIG. 4 is a plan view showing a configuration of a measuring section according to a modified example of the second embodiment.

FIG. 5 is a partial enlarged cross-sectional view showing a configuration of a measuring section according to a third embodiment.

FIG. 6 is a plan view showing a configuration of a measuring section according to a modified example of the third embodiment.

FIG. 7 is a partial enlarged cross-sectional view showing a configuration of a measuring section according to a fourth embodiment.

FIG. 8 is a partial enlarged cross-sectional view showing a configuration of a measuring section according to a fifth embodiment.

FIG. 9 is a partial enlarged cross-sectional view showing a configuration of a measuring section according to a modified example of the fifth embodiment.

FIG. 10 is a partial enlarged cross-sectional view showing a configuration of a measuring section according to another modified example of the fifth embodiment.

### MODE FOR CARRYING OUT THE INVENTION

Hereunder is a detailed description of embodiments of the present invention, with reference to the drawings.

### 1. First Embodiment

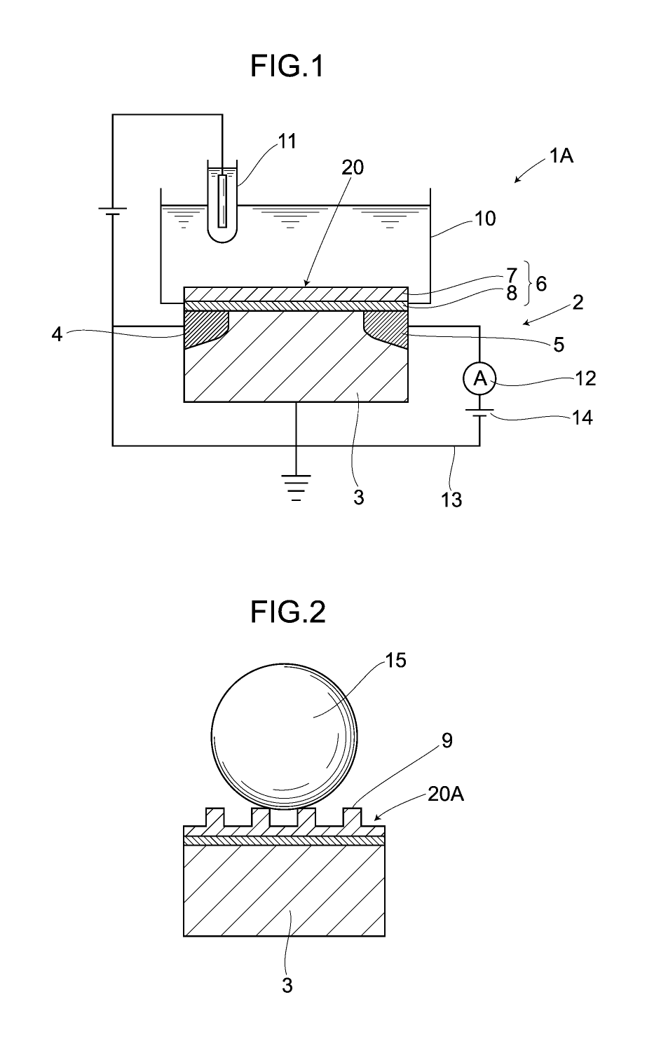

A cell measuring apparatus 1A shown in FIG. 1 comprises; a field effect transistor (hereunder called FET) 2, a solution tank 10 with a cell immersed in a solution, and a measuring section 20 with the cell in a state immersed in the solution mounted thereon, and is configured so that any change occurring in the cell can be detected by the FET 2 through the measuring section 20.

The FET 2 is such that a source 4 and a drain 5 are formed on a Si substrate 3, and is configured such that a drain current flows from the source 4 to the drain 5. Furthermore, on the surface of the Si substrate 3 there is provided a gate insulating film 6. The drain 5 and the gate insulating film 6 are electrically connected to a DC circuit 13. To the DC circuit 13 is electrically connected a DC power source 14 and an ammeter 12. The gate insulating film 6 is not particularly limited, however, in the present embodiment, this is constituted by a Ta₂O₅ film or an Si₃N₄ film 7, and an SiO₂ film 8. For a reference electrode 11 that is introduced into the solution tank 10, an Ag/AgCl electrode which is held in a KCL saturated aqueous solution, is used.

In the case of the present embodiment, in the FET sensor 2, for example when hydrogen ions having a positive charge are absorbed on the surface of the measuring section 20, the charge of the hydrogen ions and the electrons in the Si substrate 3 statically interact across the thin measuring section 20. As a result, the electron density of a channel section in the Si substrate 3 surface changes, so that the drain current changes. Consequently, by measuring the change in this drain current with the ammeter, the FET sensor 2 can electrically detect the absorption of the hydrogen ions on the surface of the measuring section 20.

In this way, in the cell measuring apparatus 1A, the respiration of a live cell such as respiration rate evaluation of a fertilized egg serving as the cell, the metabolic function of the cell, and the like, can be measured by detecting the pH change, that is, by detecting the hydrogen ions.

In the case of the present embodiment, the measuring section 20 is configured integral with the FET sensor 2, that is, the gate insulation film 6 of the FET sensor 2.

Furthermore, the cell measuring apparatus 1A can measure by simply mounting the cell on the measuring section 20. Therefore the cell can be observed using a standing microscope with the object lens arranged above the sample. Consequently, the cell measuring apparatus 1A can simultaneously measure electrically the state of a particular cell, while observing the external appearance of the cell with the microscope, and hence measurement can be performed more efficiently.

As shown in FIG. 2, in the measuring section 20A there may be formed corrugations 9 in the surface that contacts with the cell 15. The corrugations 9 are preferably small compared to the cell 15. For example, in the case of a fertilized egg with a cell 15 with a diameter of approximately 100 μm, the corrugations 9 preferably have a size of around several microns. In this way, by forming the corrugations 9 on the surface of the measuring section 20A, the surface area of the measuring section 20A that collects the charge is increased, so that the response speed can be increased. By so doing, in the case where for example a fertilized egg is applied as the cell 15, the measuring section 20A can more reliably detect the ions discharged from the fertilized egg. Therefore minute changes in the state of the fertilized egg can also be efficiently measured.

### 2. Second Embodiment

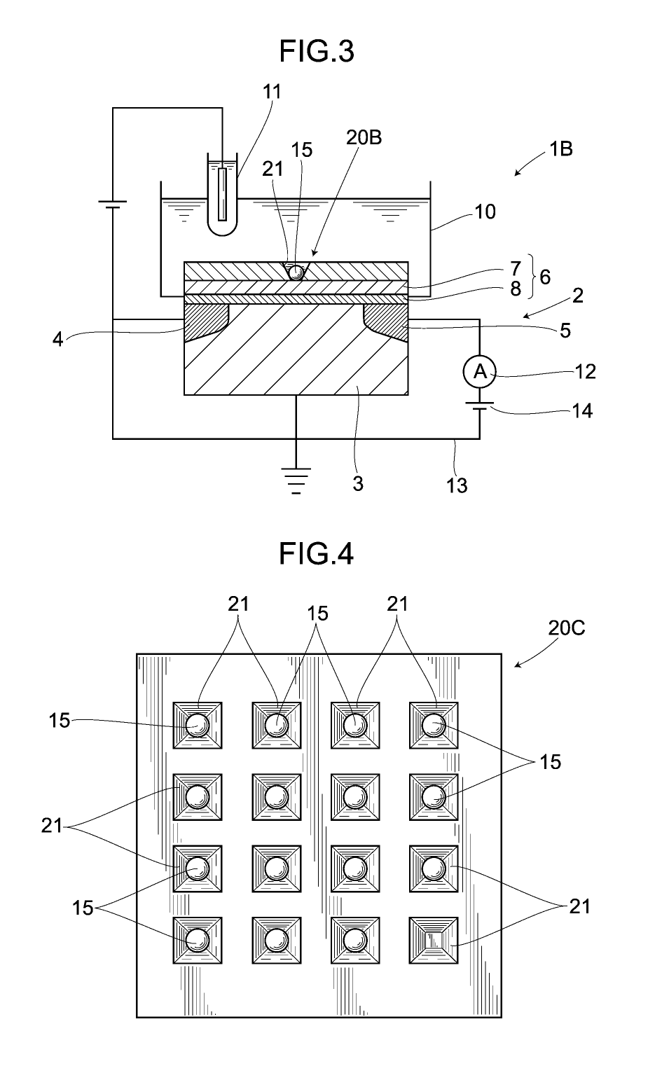

A measuring section according to a second embodiment only differs from the first embodiment in the point that there is formed an accommodating crevice that accommodates the cell 15 as a single body. Configuration the same as in FIG. 1 is denoted by the same reference symbols, and is described based on FIG. 3. A cell measuring apparatus 1B is configured such that the measuring section 20B has an accommodating cavity 21 on the gate insulation film 6.

In the case of this embodiment, the accommodating cavity 21 is formed from silicon, and is formed in a mortar shape opening upwards. The bottom face of the accommodating cavity 21 is communicated with the surface of the gate insulating film 6.

In this manner, the measuring section 20b according to this embodiment has the accommodating cavity 21, and thereby a globular cell 15, for example a fertilized egg, can be easily separated, and the state of each of the fertilized eggs can be measured. Therefore the state of each fertilized egg can be measured even more efficiently.

Furthermore, by forming the accommodating cavity 21 in the mortar shape, particularly a fertilized egg can be induced to a predetermined position, so that it can be efficiently mounted on the gate insulating film 6.

FIG. 4 shows a measuring section 20C according to a modified example of the embodiment. In the measuring section 20C, a plurality of accommodating cavities 21 are arranged in an array on a single chip. By arranging a plurality of accommodating cavities 21 on a single chip in this manner, a plurality of cells 15 can be measured in parallel, so that the size can be reduced overall, and simplification of the apparatus can be realized, enabling even more improvement in efficiently. In this case, an FET sensor (not shown in this drawing) is provided for each of the accommodating cavities 21, and adjacent FET sensors 2 are electrically isolated from each other.

### 3. Third Embodiment

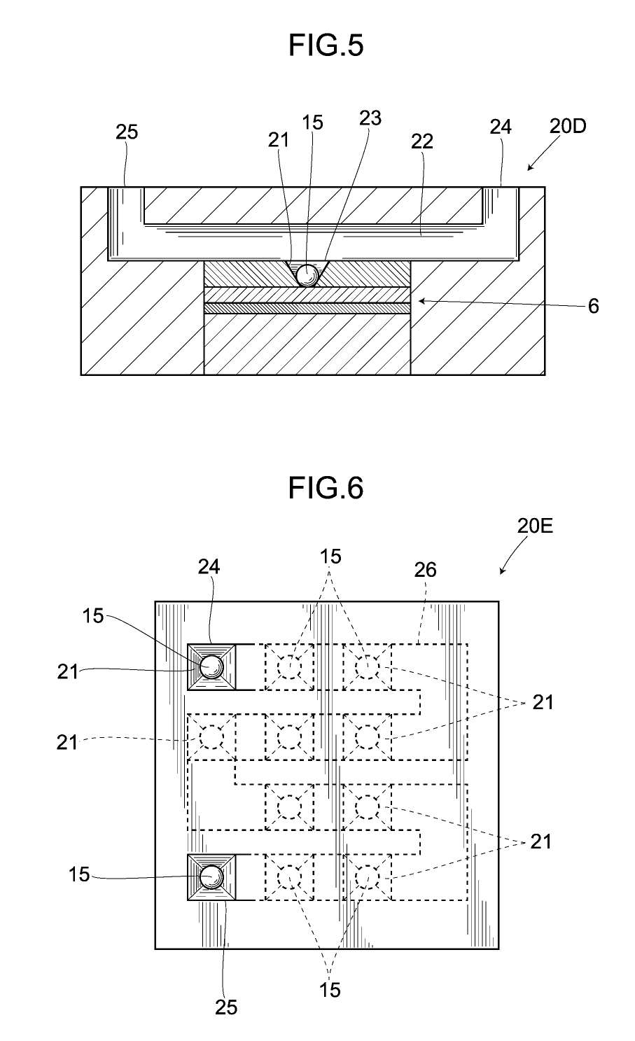

A measuring section according to this embodiment differs from the second embodiment only in that there is further formed a cell flow passage. That is to say, in a measuring section 20D shown in FIG. 5, an accommodating cavity 21 is formed in a gate insulating film 6 state, and also a cell flow path 22 in which a solution into which a plurality of cells 15 have been introduced flows, is formed on the accommodating cavity 21.

In the case of this embodiment, the cell flow path 22 is formed from silicon, and is communicated with the accommodating cavity 21 via a communicating section 23. The communicating section 23 is arranged on an upper part of the accommodating cavity 21.

In the cell flow path 22 constructed in this way, when a solution including a plurality of cells 15 flows from an inlet 24 towards an outlet 25, the cells 15 in the solution are induced into the accommodating cavity 21. The induced cells 15 move along the sidewall of the accommodating cavity 21 and are mounted on the gate insulating film 6.

In the case where the cells 15 are already accommodated inside the accommodating cavity 21, by forming the accommodating cavity 21 in a size which can accommodate a single cell 15, the cells 15 will pass over the accommodating cavity 21. Therefore the cells 15 can be reliably accommodated one at a time in each accommodating cavity 21. Consequently, the measuring section 20D can more efficiently measure the state of the cells.

As a result, in the measuring section 20D according to this embodiment, by simply having the solution containing the cells 15 flow through inside the cell flow path 22, the cells 15 can be accommodated singly in the accommodating cavity 21 reliably.

FIG. 6 shows a measuring section 20E according to a modified example of this embodiment. In the measuring section 20E, a plurality of accommodating cavities 21 are arranged in an array on a single chip, and a cell flow path 26 is formed so as to communicate with the accommodating cavity 21. An FET sensor 2 (not shown in this drawing) is provided for each of the accommodating cavities 21, and adjacent FET sensors 2 are electrically isolated from each other.

In the cell flow path 26 there is respectively provided an inlet 24 and an outlet 25 that communicate with the outer surface. Also below the inlet 24 and the outlet 25 there is formed an accommodating cavity 21.

In this case, in the cell flow path 26, when a solution including a plurality of cells 15 flows from the inlet 24 towards the outlet 25, the cells 15 in the solution are induced into the empty accommodating cavities 21 and accommodated. In this way, by a single operation of flowing the solution including the plurality of cells 15, the cells 15 can be more reliably accommodated one at a time in the plurality of accommodating cavities 21, and hence efficiency can be further improved.

Moreover, in this embodiment, on the surface of the cell flow paths 22 and 26 there can be coated an inorganic/organic compound close to the biological environment, or for which biocompatibility is high, in particular a high polymer material.

### 4. Fourth Embodiment

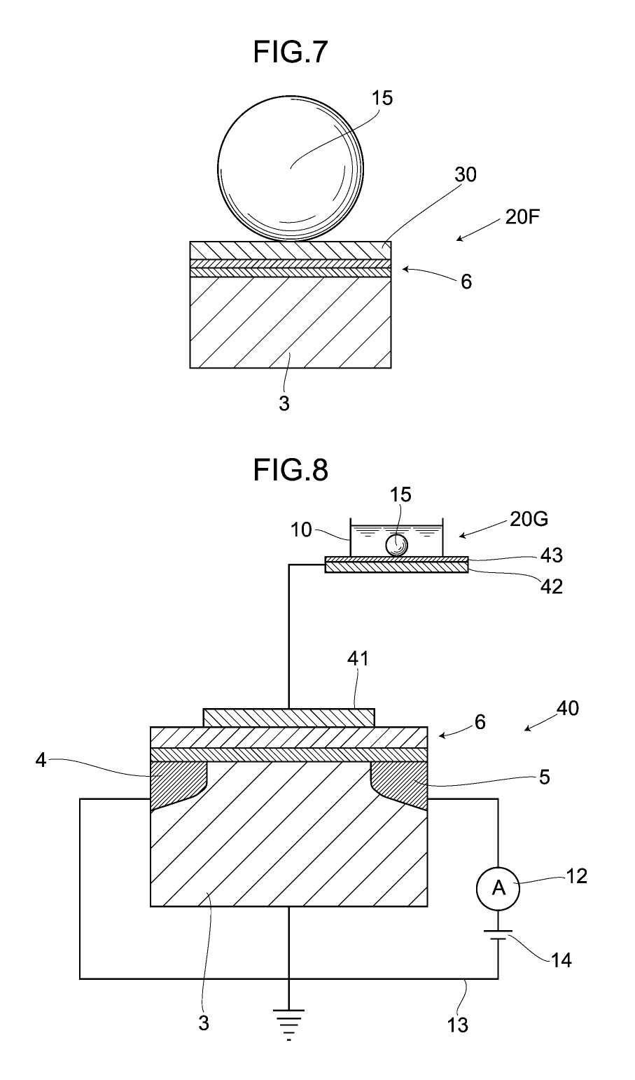

In the measuring section according to this embodiment, the only point that is different to the configuration of the first embodiment is that it is configured so as to be able to measure the mass of a cell 15. That is to say, in the measuring section 20F shown in FIG. 7, the configuration is such that a mass detecting section 30 is formed on the gate insulating film 6. In this case, the measuring section 20F is configured so that a change in the mass of a cell 15 can be detected through the mass detecting section 30. Here, for the mass detecting section 30, for example a thin film made from ZnO which is a piezoelectric material can be used.

In the measuring section 20F configured in this way, when the cell 15 is mounted, a charge is generated on the surface of the mass detecting section 30 corresponding to the pressure added by the mass of the cell 15. As a result, the electron density of the channel section in the Si substrate 3 surface changes, and the drain current changes. Consequently by measuring this change in drain current with an ammeter, the mass of the cell 15 can be electrically detected. As a result, the measuring section 20F according to this embodiment can efficiently measure the mass of the cell 15.

### 5. Fifth Embodiment

The measuring section according to this embodiment differs to the first embodiment in that it is provided separate to the FET sensor. That is to say, the measuring section 20G shown in FIG. 8 is electrically connected to a gate electrode 41 that is formed on a gate insulating film 6 of a FET sensor 40.

This measuring section 20G is configured from a transparent material, and has a substrate 42 and a charge detecting section 43 formed on one side surface of the substrate 42. The substrate 42 is formed for example from ITO (indium tin oxide), ZnO, or the like.

For the charge detecting section 43, a functional sensitive membrane which efficiently detects ions released from the cell 15 is preferably used. The relation between the cell function and the ions corresponding to the cell function, is illustrated below. As the cell function, the apoptosis (cell death) can be measured by detecting the potassium ions or the chloride ions. As the cell function, a stroke of a nerve cell or a muscle cell, can be measured by detecting the sodium ions. As the cell function, the calcium phosphate released from the bone cell can be measured by detecting the calcium ions.

Regarding the functionally sensitive membrane, this can be variously selected for the membrane function from the viewpoint of performing specialized measurements. For example, for potassium ions, potassium ionophore, for chloride ions, chloride ion ionophore, for sodium ions, sodium ion ionophore, for calcium ions, calcium ion ionophore, and the like, can be applied.

Furthermore, corrugations may be formed on the surface of the charge detecting section 43. For the corrugations, it is desirable to form these in a size of around several microns. By forming corrugations 9 on the surface of the charge detecting section 43, the surface area of the charge detecting section 43 that collects the charge is increased so that the response speed can be increased. By so doing, in the case where for example a fertilized eggs is applied as the cell 15, the charge detecting section 43 can more reliably detected the ions based on the respiration of the fertilized egg, or the ions discharged from the fertilized. Therefore, minute changes in the state of the fertilized egg can also be efficiently measured.

Regarding the corrugations, these can be formed for example by coating the material constituting the charge detecting section 43 on the substrate, then spreading beads over the surface, and fixing these to the material, then removing the beads, so as to transfer the shape of the beads to the charge detecting section 43.

In this manner, by configuring the measuring section 20G according to this embodiment, with the FET sensor 40 provided separate, and using a transparent material, the cells 15 mounted on the measuring portion can be observed with an inverted microscope with the object lens arranged on the lower side of the specimen. Consequently, the state of the cell 15 can be simultaneously measured electrically while observing the external appearance of the cell 15 with the microscope, and hence measurement can be performed more efficiently. Furthermore, since this can be observed with an inverted microscope with the object lens arranged on the lower side of the specimen, versatility can be improved.

### MODIFIED EXAMPLES

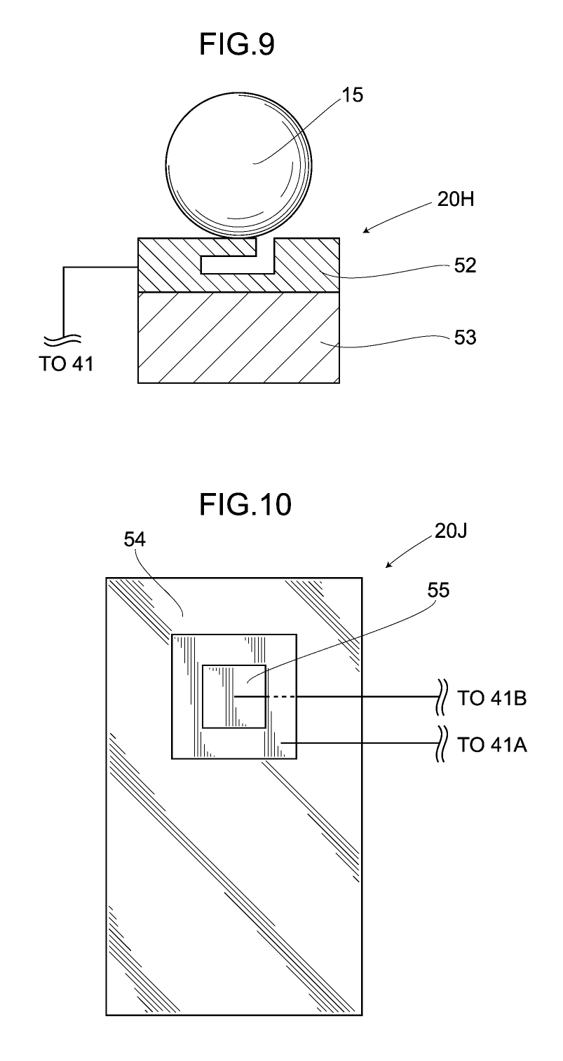

In the present embodiment, a case where a charge detecting section is provided on the measurement section has been described. However the present invention is not limited to this, and a mass detecting section may be provided. In this case, as shown in FIG. 9, a mass detecting section 52 may be formed in a cantilever beam shape. In this case, the substrate 53 is made from glass or the like, and the mass detecting section 52 is electrically connected to a gate electrode 41 of a FET sensor 40.

Furthermore, in a measuring section 20J shown in FIG. 10, a charge detecting section 54 and a mass detecting section 55 are integrally provided. In the case of this modified example, the mass detecting section 55 on which the cell 15 is mounted is provided in a square pattern in plan view, and the charge detecting section 54 is formed so as to surround the perimeter of the mass detecting section 55. The charge detecting section 54 and the mass detecting section 55 are electrically connected to respective gate electrodes 41A and 41B of separate FET sensors.

In the measuring section 20J configured in this manner, by mounting the cell 15 on the mass detecting section 55, the weight of the cell 15 can be detected. At the same time, the ions discharged from the cell 15 can be detected by the charge detecting section 54 provided in the perimeter of the mass detecting section 55, so that the state of the cell 15 can be measured electrically. As a result, in a single configuration, the measuring section 20J can simultaneously measure the charge based on the mass change, and the charge of the ion or the unique molecule. Therefore, complex functions of the cell can be more efficiently measured.

### 6. Modified Example

The present invention is not limited to the above embodiments, and can be appropriately modified within the scope of the gist of the present invention.

For example, in the first embodiment, the point where observation can be made with a standing microscope was described. However if the FET sensor itself can be formed from a transparent material such as a transparent amorphous oxide semiconductor (indium-lead-gallium oxide etc.) or the like, then observation can also be made with an inverted microscope.

Furthermore, in the second, third, and fourth embodiments, the case where the measuring section is provided integrally with the FET sensor was described. However, the present invention is not limited to this, and similar to the fifth embodiment, the measuring section may be provided electrically connected to the gate electrode of the FET sensor, and can also be provided separate to the FET sensor. In this case, the measuring section is preferably constituted by a transparent material.

Moreover, in the fifth embodiment, the case where a measuring section having a charge detecting section and a mass detecting section separate to the FET was described. However the present invention is not limited to this, and these may be provided integral with the FET sensor.

Furthermore, for example the fifth embodiment may be applied to the second, third, and fourth embodiments, and the respective embodiments may also be applied appropriately combined with each other.

1. A cell measuring apparatus provided with a first FET sensor, wherein there is provided in a measurement section on which is mounted a cell immersed in a solution, an accommodating cavity for accommodating said cell.

2. A cell measuring apparatus according to claim 1, wherein said accommodating cavity is formed in a mortar shape.

3. A cell measuring apparatus according to either one of claim 1 and claim 2, wherein said measuring section is constituted by a transparent material.

4. A cell measuring apparatus according to claim 3, wherein said measuring section is electrically connected to a gate electrode of said first FET sensor, and is provided separate to said first FET sensor.

5. A cell measuring apparatus according to claim 4, wherein said measuring section is formed with a charge detecting section.

6. A cell measuring apparatus according to claim 5, wherein a mass detecting section formed from a transparent material, is provided on said measuring section, and said mass detecting section is electrically connected to a gate electrode of a second FET sensor.

7. A cell measuring apparatus according to claim 6, wherein said mass detecting section is constituted by a piezoelectric material, and is formed in a cantilever beam shape.

8. A cell measuring apparatus according to claim 6, wherein said charge detecting section is formed so as to surround a periphery of said load detecting section.

9. A cell measuring apparatus according to claim 1, wherein said measuring section is formed with a cell flow path in which said solution including said cell flows, and said cell flow path is communicated with said accommodating cavity.

10. A cell measuring apparatus according to claim 1, wherein corrugations are formed on a surface of said measuring section on which said cells are mounted.
